(19) United States
(12) Patent Application Publication
(10) Pub. No.: US 2023/0101209 A1
(43) Pub. Date: Mar. 30, 2023

(54) ELECTRONIC DEVICE MOUNTING SCREW ASSEMBLIES

(71) Applicant: Hewlett-Packard Development Company, L.P., Spring, TX (US)

(72) Inventors: Andrew Shane ELSEY, Spring, TX (US); Baosheng Zhang, Spring, TX (US); Hui HE, Spring, TX (US)

(21) Appl. No.: 17/794,936

(22) PCT Filed: Jan. 24, 2020
(86) PCT No.: PCT/US2020/015050

§ 371 Date: Jul. 22, 2022

(51) Int. Cl. H05K 5/00; G06F 1/18

(52) U.S. Cl. CPC H05K 5/0008; G06F 1/181

(57) ABSTRACT

An example electronic device is disclosed that includes a housing including a first external cover and a second external cover opposite the first external cover. In addition, the electronic device includes an electronic component disposed within the housing, between an inner surface of the first external cover and an inner surface of the second external cover. The electronic component is mounted to the first external cover with a mounting screw assembly, and the mounting screw assembly is engaged with the inner surface of the second external cover.

### BACKGROUND

Electronic devices may include a housing that contains electronic components (e.g., a central processing unit (CPU), a graphics processing unit (GPU), a power source, etc.). These various electronic components may be secured within the housing via mounting screws or other suitable mounting devices.

### BRIEF DESCRIPTION OF THE DRAWINGS

Various examples will be described below referring to the following figures:

FIG. 1 is a schematic cross-sectional view of a housing of an electronic device, including a mounting screw assembly for securing an electronic component within the housing according to some examples;

FIG. 2 is a schematic cross-sectional view of a housing of an electronic device, including a mounting screw assembly for securing an electronic component within the housing according to some examples;

FIG. 3 is a schematic cross-sectional view of a housing of an electronic device, including a mounting screw assembly for securing an electronic component within the housing according to some examples; and

FIG. 4 is an enlarged schematic cross-sectional view of one of the mounting screws of the mounting screw assembly of FIG. 3 according to some examples.

### DETAILED DESCRIPTION

In the figures, certain features and components disclosed herein may be shown exaggerated in scale or in somewhat schematic form, and some details of certain elements may not be shown in the interest of clarity and conciseness. In some of the figures, in order to improve clarity and conciseness, a component or an aspect of a component may be omitted.

In the following discussion and in the claims, the terms “including” and “comprising” are used in an open-ended fashion, and thus should be interpreted to mean “including, but not limited to . . . .” Also, the term “couple” or “couples” is intended to be broad enough to encompass both indirect and direct connections. Thus, if a first device couples to a second device, that connection may be through a direct connection or through an indirect connection via other devices, components, and connections. In addition, as used herein, the terms “axial” and “axially” generally mean along or parallel to a given axis, while the terms “radial” and “radially” generally mean perpendicular to the given axis. For instance, an axial distance refers to a distance measured along or parallel to the axis, and a radial distance means a distance measured perpendicular to the axis.

As used herein, including in the claims, the word “or” is used in an inclusive manner. For example, “A or B” means any of the following: “A” alone, “B” alone, or both “A” and “B.” In addition, when used herein including the claims, the word “generally” or “substantially” means within a range of plus or minus 10% of the stated value.

As previously described, electronic component(s) may be secured within a housing of an electronic device with mounting screws or other suitable mounting devices. In addition, spacing may be maintained about the electronic components within the housing (e.g., spacing from other electronic components, the housing itself, etc.) so as to avoid unintended engagement with the electronic components during operations. In order to reduce weight as well as manufacturing costs, the wall thickness of an electronic device housing may be reduced. As a result, the stiffness of the walls of the electronic device housing may also be reduced, thereby increasing the chances that a wall or surface of the electronic device housing may be deflected during operations so as to contact (and therefore potentially damage) electronic components disposed therein. Accordingly, examples disclosed herein include mounting screw assemblies for securing an electronic component within a housing of an electronic device that are to provide additional support for an external cover or wall of the electronic device and therefore prevent or restrict the deflection thereof during operations.

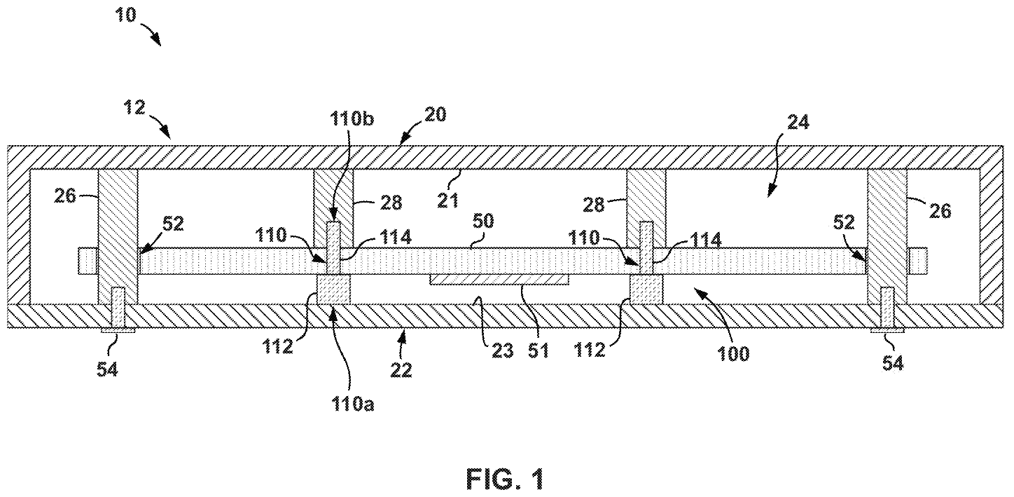

Referring now to FIG. 1, a housing 12 of an electronic device 10 is shown. In some examples, the electronic device 10 may comprise, for instance, a laptop computer, a tablet computer, a smartphone, etc. Housing 12 includes a first or upper external cover 20 and a second or lower external cover 22. The upper external cover 20 includes an inner surface 21, and the lower external cover 22 includes an inner surface 23. When external covers 20, 22 are coupled to one another (e.g., as shown in FIG. 1), the inner surfaces 21, 23 define an inner cavity or space 24 within the housing 12.

In some examples, the electronic device 10 may comprise a laptop computer and the housing 12 may comprise one of a pair of housings coupled to one another via a hinge (not shown). In these examples, the upper external cover 20 may form the upper surface of the housing 12 that supports a keyboard (not shown) and clickpad (not shown), and the lower external cover 22 may form the lower surface of the housing 12 that may be engaged with a support surface (e.g., a table, counter-top, floor, desk, etc.) during operations with the electronic device 10. In addition, in these examples, the upper external cover 20 may be referred to as a “C-cover,” and the lower external cover 22 may be referred to as a “D-Cover.”

Referring still to FIG. 1, a plurality of extensions 26, 28 extend from and are coupled to the upper external cover 20. In particular, the plurality of extensions 26, 28 includes a set of first extensions 26 and a set of second extensions 28. The first extensions 26 and second extensions 28 may be coupled or mounted to the upper external cover 20, or may be integrally formed as a monolithic, unitary, single-piece body with the upper external cover 20. The lower external cover 22 may be mounted to the upper external cover 20 by inserting a plurality of mounting screws 54 through the lower external cover 22 and threadably engaging the mounting screws 54 within the set of first extensions 26.

A substrate 50 is disposed within inner cavity 24. The substrate 50 supports an electronic component 51 (or a plurality of electronic components 51) thereon, such as, for instance, processors, hard-drives, CPU, GPU, etc. Substrate 50 may comprise a circuit board (e.g., a printed circuit board) or any other suitable substrate or support surface for an electronic component or plurality thereof (e.g., electronic component 51). Generally speaking, substrate 50 and therefore electronic component 51 are secured within inner cavity 24 via a mounting screw assembly 100.

Mounting screw assembly 100 comprises a plurality of mounting screws 110. Each mounting screw 110 includes a first end 110a, and a second end 110b opposite first end 110a. A screw head 112 is disposed at first end 110a, and a threaded portion 114 extends from screw head 112 to the second end 110b. As shown in FIG. 1, electronic component 51 is secured within the inner cavity 24 by engaging the substrate 50 with the second extensions 28. Thereafter, the mounting screws 110 are inserted through the substrate 50 and threadably engaging the threaded portions 114 within the second extensions 28 until substrate 50 is captured or secured between the screw heads 112 of mounting screws 110 and the second extensions 28. As shown in FIG. 1, the first extensions 26 (or some of the first extensions 26) may extend through apertures or through-holes 52 in the substrate 50.

The screw heads 112 of the mounting screws 110 are elongated so as to engage with (or be proximate to) the inner surface 23 of lower external cover 22 (e.g., when lower external cover 22 is coupled to external cover 20 as shown in FIG. 1). As a result, the lower external cover 22 is prevented from deflecting inward toward electronic component 51 on substrate 50 due to engagement with screw heads 112 during operations. Thus, the mounting screws 110 of mounting screw assembly 100 may impart additional stiffness and rigidity to the lower external cover 22 of housing 12.

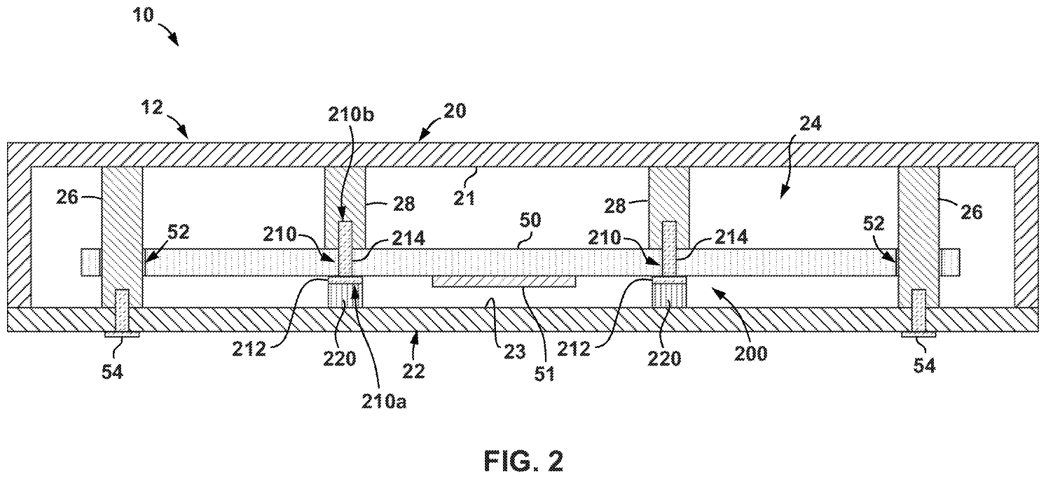

Referring now to FIG. 2, in some examples, substrate 50 and electronic component 51 may be secured within inner cavity 24 of housing 12 via a mounting screw assembly 200 (e.g., either in addition to or in lieu of the other screw mounting assemblies discussed herein). Screw mounting assembly 200 includes a plurality of mounting screws 210. Each mounting screw 210 includes a first end 210a and a second end 210b opposite first end 210a. A screw head 212 is disposed at first end 210a, and a threaded portion 214 extends from screw head 212 to the second end 210b. In addition, a spacer 220 is engaged with and extends from the first end 210a of mounting screw 210 (e.g., at screw head 212). The spacer 220 may be formed from a resilient material (e.g., an elastomeric material, such as, for instance, natural or synthetic rubber). In particular, the spacer 220 may be formed of a material that has a higher resilience and/or lower modulus of elasticity than the material forming mounting screws 210 (which, in some examples, may comprise a metallic material such as, for instance, steel).

As shown in FIG. 2, substrate 50 and electronic component 51 are secured within the inner cavity 24 by engaging the substrate 50 with the second extensions 28 as previously described. Thereafter, the mounting screws 210 are inserted through the substrate 50 and threadably engaging the threaded portions 214 within the second extensions 28 until substrate 50 is captured or secured between the screw heads 212 of mounting screws 210 and the second extensions 28 in the manner previously described above for mounting screws 110.

The spacers 220 are secured to the screw heads 212 so spacers 220 are to engage with (or be proximate to) the inner surface 23 of lower external cover 22 (e.g., when lower external cover 22 is coupled to upper external cover 20 as shown in FIG. 2). As a result, the lower external cover 22 is prevented from deflecting inward toward electronic component 51 on substrate 50 due to engagement with spacer 220 during operations. Thus, the spacers 220 of mounting screw assembly 200 may impart additional stiffness and rigidity to the lower external cover 22 of housing 12. In addition, because the spacers 220 are formed of a material having a relatively high resilience (e.g., such as an elastomeric material as previously described above), any deflection of the lower external cover 22 may be damped or absorbed by the spacers 220 so that damage to the lower external cover 22, second extensions 28, and/or upper external cover 20 is prevented (or reduced).

In some examples, the spacers 220 may be secured to the screw heads 212 after mounting screws 210 are fully threadably engaged with second extensions 28 (e.g., such as with an adhesive). In some examples, the spacers 220 are secured to the screw heads 212 before the mounting screws 210 are threadably engaged with the second extensions 28. In some of these examples, screw head 212 (and possibly spacer 220) may include facets so as to allow a suitable tool to transfer torque to the mounting screws 212 during operations. In particular, in some examples, the screw heads 212 (and possibly spacers 220) have a hexagonal shape or cross-section, and a suitable hexagonal torque wrench is used to threadably engage the screws 210 within second extensions 28. In other examples, the spacers 220 may include a throughbore or aperture therethrough (not shown) that is to provide access to a drive feature (e.g., such as a linear slot, Philips-head drive, square drive, etc.) on the screw heads 212. Thus, during operations, a screwdriver (or other suitable tool) may be inserted through the apertures (not shown) in the spacers 220 to engage with the drive features on the screw heads 212 and threadably engage the mounting screws 210 within the second extensions 28 as previously described above.

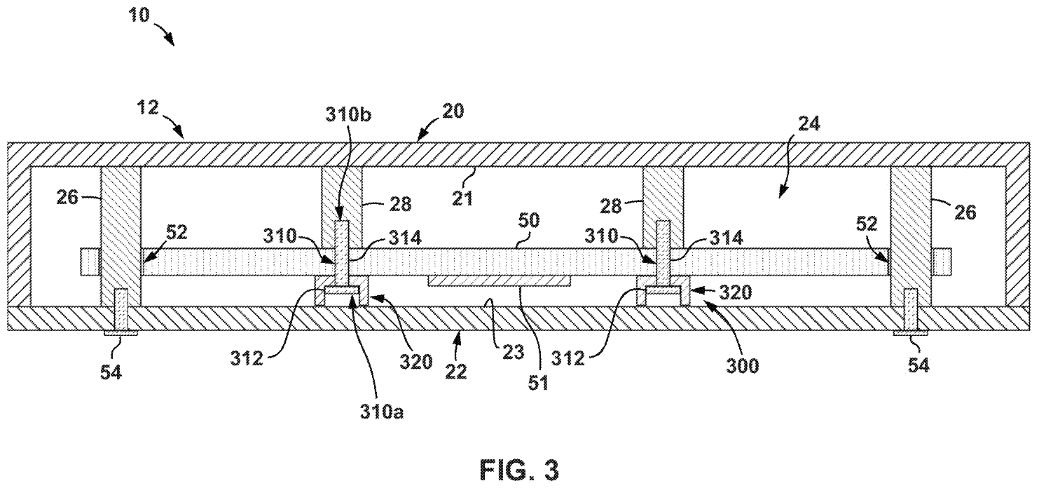

Referring now to FIG. 3, in some examples, substrate 50 and electronic component 51 may be secured within inner cavity 24 of housing 12 via a mounting screw assembly 300 (e.g., either in addition to or in lieu of the other screw mounting assemblies discussed herein). Mounting screw assembly 300 includes a plurality of mounting screws 310. Each mounting screw 310 includes a first end 310a and a second end 310b opposite first end 310a. A screw head 312 is disposed at first end 310a, and a threaded portion 314 extends from screw head 312 to the second end 310b. In addition, a washer 320 is disposed about threaded portion 314 and engaged with screw head 312.

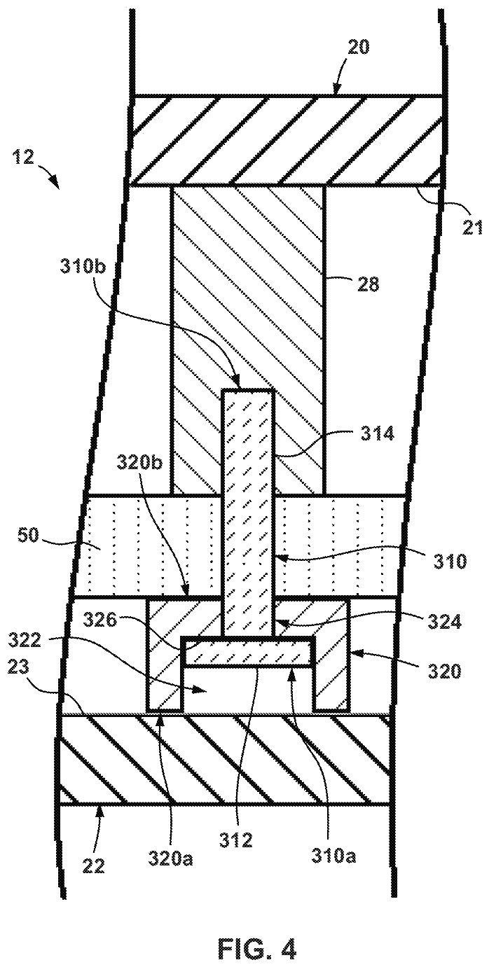

Reference is now made to FIG. 4, in which one mounting screw 310 and washer 320 is shown engaged with substrate 50 in more detail. Each washer 320 may include a first end 320a, a second end 320b opposite first end 320a, and a counter-bore or recess 322 extending from first end 320a. In addition, a throughbore or aperture 324 extends from the second end 320b to the recess 322. The throughbore 324 has a smaller diameter than the recess 322, so that a shoulder 326 is formed within recess 322. As was previously described above for the spacers 220 (see e.g., FIG. 2), the washers 320 may be formed from a resilient material (e.g., an elastomeric material, such as, for instance, natural or synthetic rubber). In particular, the washers 320 may be formed of a material that has a higher resilience and/or lower modulus of elasticity than the material forming mounting screws 310 (which may comprise a metallic material such as, for instance, steel).

As shown in FIGS. 3 and 4, substrate 50 and electronic component 51 are secured within the inner cavity 24 by engaging the substrate 50 with the second extensions 28 as previously described. Thereafter, the mounting screws 310 are inserted through the washers 320 and substrate 50 and the threaded portions 214 are threadably engaged within the second extensions 28 until substrate 50 and washers 320 are captured or secured between the screw heads 312 of mounting screws 310 and the second extensions 28. More specifically, the mounting screws 310 are inserted through the washers 320 so that the screw heads 312 engage with the shoulders 326 within recesses 322 of washers 320. Thereafter, the threaded portions 314 of mounting screws 310 are inserted through the substrate 50 and threadably engaged within second extensions 28 until the screw heads 312 compress the second ends 320b of washers 320 against the substrate 50, to thereby secure substrate 50 and electronic component 51 to second extensions 28.

The first ends 320a of washers 320 extend past the screw heads 312 so as to engage with (or be proximate to) the inner surface 23 of lower external cover 22 (e.g., when lower external cover 22 is coupled to upper external cover 20 as shown in FIG. 3). As a result, the lower external cover 22 is prevented from deflecting inward toward electronic component 51 due to engagement with first ends 320a of washers 320 during operations. Thus, the washers 320 of mounting screw assembly 300 (particularly the first ends 320a of washers 320) may impart additional stiffness and rigidity to the lower external cover 22 of housing 12. In addition, because the washers 320 are formed of a material having a relatively high resilience (e.g., such as an elastomeric material as previously described above), any deflection of the lower external cover 22 may be damped or absorbed by the washers 320 so that damage to the lower external cover 22 is prevented (or reduced).

While examples disclosed herein have included mounting screw assemblies for preventing deflection of a lower external cover (e.g., lower external cover 22) of an electronic device (e.g., electronic device 10), in other examples, the mounting screw assemblies (e.g., mounting screw assemblies 100, 200, 300, etc.) may be utilized to prevent or restrict the deflection of other covers of an electronic device (e.g., such as upper external cover 20 shown in FIGS. 1-4). In addition, as previously described above, the mounting screw assemblies (e.g., mounting screw assemblies 100, 200, 300, etc.) may be utilized within various types of electronic devices, such as, for instance, tablet computers, all-in-one computers, smartphones, personal data assistants, servers, music players, etc. Thus, any mention of a laptop computer should not be interpreted as limiting the electronic devices that the disclosed mounting screw assemblies may be utilized within in various examples.

The examples disclosed herein include mounting screw assemblies (e.g., mounting screw assemblies 100, 200, 300, etc.) for securing an electronic component (e.g., electronic component 51) within a housing (e.g., housing 12) of an electronic device (e.g., electronic device 10) that are to provide additional support for an external cover or wall (e.g., lower external cover 22) of the electronic device and therefore prevent or restrict the deflection thereof during operations. As a result, electronic devices may employ relatively lightweight, less stiff external covers while still avoiding damage to electronic components disposed therein.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An electronic device, comprising:
a housing including a first external cover and a second external cover opposite the first external cover; and
an electronic component disposed within the housing, between an inner surface of the first external cover and an inner surface of the second external cover,
wherein the electronic component is mounted to the first external cover with a mounting screw assembly, and
wherein the mounting screw assembly is engaged with the inner surface of the second external cover.

2. The electronic device of claim 1, wherein the mounting screw assembly comprises:
a screw comprising a first end, a second end opposite the first end, a screw head at the first end, and a threaded portion extending from the screw head to the second end,
wherein the threaded portion is threadably engaged with an extension extending from the internal surface of the first external cover, and the screw head is engaged with the inner surface of the second external cover.

3. The electronic device of claim 1, wherein the mounting screw assembly comprises:
a screw including a first end and a second end opposite the first end, wherein the second end is engaged with an extension extending from the internal surface of the first external cover; and
a spacer engaged between the first end of the screw and the inner surface of the second external cover.

4. The electronic device of claim 3, wherein the spacer comprises a material that has a higher resilience than a material of the screw.

5. The electronic device of claim 1, wherein the mounting screw assembly comprises:
a screw; and
a washer,
wherein the screw extends through the washer and is threadably engaged within an extension extending from the inner surface of the first external cover, and
wherein the washer is engaged with the inner surface of the second external cover.

6. The electronic device of claim 5, wherein the washer comprises a material that has a higher resilience than a material of the screw.

7. An electronic device, comprising:
a housing including a first external cover and a second external cover opposite the first external cover;
an extension extending from an inner surface of the first external cover; and
a circuit board disposed within the housing, between the first external cover and the second external cover,
wherein the circuit board is mounted to the extension with a mounting screw assembly, and
wherein the mounting screw assembly is engaged with an inner surface of the second external cover.

8. The electronic device of claim 7, wherein the mounting screw assembly comprises:
a screw including a first end and a second end opposite the first end, wherein the second end is inserted through the circuit board and into the extension; and
a spacer engaged between the first end of the screw and the inner surface of the second external cover.

9. The electronic device of claim 8, wherein the spacer comprises material that has a higher resilience than a material of the screw.

10. The electronic device of claim 7, wherein the mounting screw assembly comprises:
a screw; and
a washer,
wherein the screw extends through the washer and the circuit board, and is threadably engaged within the extension, and
wherein the washer is engaged with the inner surface of the second external cover.

11. The electronic device of claim 10, wherein the washer comprises material that has a higher resilience than a material of the mounting screw.

12. An electronic device, comprising:
a housing including a first external cover and a second external cover opposite the first external cover;
a substrate disposed within the housing, between an inner surface of the first external cover and an inner surface of the second external cover;
an electronic component mounted to the substrate, and
an extension extending from the inner surface of the first external cover;
wherein the substrate is mounted to the extension with a mounting screw assembly, and
wherein the mounting screw assembly is engaged with the inner surface of the second external cover.

13. The electronic device of claim 12, wherein the mounting screw assembly comprises a screw and an engagement member, wherein the screw extends through the substrate and is threadably engaged with the extension, and wherein the engagement member is engaged with the screw and the inner surface of the second external cover.

14. The electronic device of claim 13, wherein the engagement member comprises a material that has a higher resilience than a material of the mounting screw.

15. The electronic device of claim 12, wherein the mounting screw assembly comprises:
a screw comprising a first end, a second end opposite the first end, a screw head at the first end, and a threaded portion extending from the screw head to the second end,
wherein the threaded portion is threadably engaged with the extension, and the screw head is engaged with the inner surface of the second external cover.
